(19) United States
(12) Patent Application Publication
(10) Pub. No.: US 2020/0274083 A1
(43) Pub. Date: Aug. 27, 2020

(54) FLEXIBLE OLED DISPLAY DEVICE AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Tianfu GUO, Wuhan, Hubei (CN)

(21) Appl. No.: 16/476,291

(22) PCT Filed: Mar. 21, 2019
(86) PCT No.: PCT/CN2019/079029

§ 371 Date: Jul. 7, 2019

(30) Foreign Application Priority Data
Feb. 25, 2019 (CN) 201910139080.1

(51) Int. Cl. H01L 51/00; H01L 27/32; H01L 51/52; H01L 51/56

(52) U.S. Cl. CPC H01L 51/0097; H01L 27/3246; H01L 27/3258; H01L 51/5253; H01L 2227/326; H01L 51/003; H01L 51/56; H01L 2251/5338; H01L 51/0018

(57) ABSTRACT

A flexible OLED device and a manufacturing method thereof. The flexible OLED device includes a flexible substrate, an insulating layer, a thin film transistor layer, a planarization layer, a pixel-defining layer, an organic light emitting layer and a thin film encapsulation layer. At least one of the planarization layer, a protrusion of the pixel-defining layer or the thin film encapsulation layer is provided with a notch passing through at least one film layer in which the planarization layer, the protrusion of pixel-defining layer or the thin film encapsulation layer is located, wherein the notch is formed by photolithography. The notch is filled with a first material. By utilizing flexibility of the first material, flexibility of a flexible OLED device is improved, and the flexible OLED device that can be bent inward and outward is realized.

### FIELD OF INVENTION

The present invention relates to the field of display technology, in particular to a flexible OLED display device and a manufacturing method thereof.

### BACKGROUND OF INVENTION

A basic structure of an organic light emitting diode (OLED) is like a sandwich structure that a thin and transparent indium tin oxide (ITO) with semiconductor properties is connected to a positive electrode of an electricity, an organic layer is disposed on the ITO, and a metal-surface cathode is disposed on the organic layer. The organic layer includes a hole-transport layer (HTL), an electroluminescent layer (EL), and an electron-transport layer (ETL). When the electric power is supplied to an appropriate voltage, holes, and electrons are injected to the EL from the ITO and the cathode respectively, and excitons (electron-hole pairs) in an excited state are formed under a certain probability by a Coulomb force. The excitons in an excited state are very unstable in a normal environment and will transfer energy to luminous materials, thereby making the luminous materials be transferred into their excited states that can relax down into the ground state radiatively by emitting photons, and light is emitted. Red light, green light, and blue light can be generated according to types of luminous materials.

Different from a Thin Film Transistor-Liquid Crystal Display (TFT-LCD), an OLED can produce their own light without a backlight. Therefore, the OLED has wide viewing angles and high brightness. Secondly, the OLED has various advantages, such as low voltage demand, high power saving efficiency, fast response rate, light weight, thin thickness, simple structure, low cost, almost infinite contrast, and low power consumption. The OLED has become one of the most important display technologies nowadays. Furthermore, the OLED is gradually replacing TFT-LCD and is expected to become a next-generation main display technology after LCD.

### SUMMARY OF INVENTION

### Technical Problems

A great advantage of an OLED is that the OLED can be made into a flexible display panel with bendability. OLED products in the industry have been marketized, and many OLED products have been applied to electronic products in life nowadays. The most competitive advantage of OLED devices is their flexibility. Enhancing the flexibility of the OLED devices to the application requirements of wearable products will inevitably lead to a revolution of electronic products. The flexibility of conventional OLED devices needs to be improved to realize wearable OLED devices. Therefore, there is a need to provide a new flexible OLED device and a fabrication method thereof to improve the flexibility of the conventional OLED devices.

### Solutions of the Technical Problems

A purpose of the present invention is to provide a flexible OLED device and a fabrication method thereof to improve the flexibility of the OLED devices.

To solve the above problems, an embodiment of the present invention provides a flexible OLED device, including: a flexible substrate; an insulating layer disposed on the flexible substrate; a thin film transistor layer disposed on the insulation layer; a planarization layer disposed on the thin film transistor layer; a pixel defining layer disposed on the planarization layer, wherein a plurality of openings and a plurality of protrusions are disposed on the pixel defining layer alternatively; an organic emitting layer disposed on the pixel defining layer; and a thin film encapsulation layer covering the pixel defining layer and the organic emitting layer. At least one of the planarization layer, the protrusion of the pixel defining layer and the thin film encapsulation layer is provided with a notch passing through at least one film layer in which the planarization layer, the protrusion of the pixel defining layer and the thin film encapsulation layer is located, and the notch is filled with a first material.

Furthermore, the plurality of notches are formed in a film layer in which each of the notches is defined, and the notches are regularly spaced.

Furthermore, each of the notches includes a bottom surface; a left side surface and a right side surface connected to a film layer in which each of the notches is defined. At least one of the left side surface and the right side surface of each of the notches is in the shape of a curved surface, a wavy surface, a single bending surface, a continuous bending surface, a concave surface, a convex surface or a combination of the above shapes.

Furthermore, the left side surface and the right side surface of each of the notches are in the shape of a single bending surface. Bending directions of the left side surface and the right side surface of each of the notches are the same. A bending angle between the left side surface and the right side surface of each of the notches ranges from 60 degrees to 180 degrees.

Furthermore, the left side surface and the right side surface of each of the notches are in the shape of a single bending surface. Bending directions of the left side surface and the right side surface of each of the notches are opposite. A bending angle between the left side surface and the right side surface of each of the notches ranges from 60 degrees to 180 degrees.

Furthermore, an elastic modulus of the first material is less than 100 Mpa.

Furthermore, the first material is polyvinylchloride (PVC) or polyolefin (POE).

Another embodiment of the present invention provides a manufacturing method of a flexible OLED device, including a plurality of steps described as below;

S1, providing a glass substrate, coating polyimide (PI) liquid on the glass substrate by a PI coater, and then manufacturing a flexible substrate by a high-temperature curing. An insulating layer, a thin film transistor layer, a planarization layer, and a pixel defining layer are sequentially formed on the flexible substrate, wherein a plurality of openings and a plurality of protrusions are disposed on the pixel defining layer alternatively.

S2, forming a notch passing through the film layer of at least one of the planarization layer, the protrusion of the pixel defining layer and a thin film encapsulation layer in which the notch is defined by photolithography, and then filling the notch with the first material.

S3, exposing and developing the pixel defining layer.

S4, forming an organic emitting layer and the thin film encapsulation layer on the pixel defining layer.

### Beneficial Effect

The present invention provides a flexible OLED device and a fabrication method thereof. At least one of the planarization layer, the protrusion of pixel defining layer and the thin film encapsulation layer is provided with a notch passing through at least one film layer in which the planarization layer, the protrusion of the pixel defining layer or the thin film encapsulation layer is located. At least one of a left side surface and a right side surface of each of the notches is in the shape of a curved surface, a wavy surface, a single bending surface, a continuous bending surface, a concave surface, a convex surface or a combination of the above shapes. The notch is filled with a first material, wherein an elastic modulus of the first material is less than 100 Mpa. By utilizing the first material, flexibility of a flexible OLED device is improved, and the flexible OLED device that can be bent inward and outward is realized.

### DESCRIPTION OF DRAWINGS

In order to more clearly illustrate the technical solutions in embodiments of the present invention, drawings used in the description of embodiments will be briefly described below. Apparently, the drawings in the following description are only some embodiments of the present invention, those skilled in the art can derive other drawings according to these drawings without paying creative efforts.

FIG. 1 is a schematic structural view showing a flexible OLED device of the first embodiment according to the present invention.

FIG. 2 is a schematic structural view showing a flexible OLED device of the second embodiment according to the present invention.

FIG. 3 is a first process schematic view showing a flexible OLED device of the first embodiment according to the present invention.

FIG. 4 is a second process schematic view showing a flexible OLED device of the first embodiment according to the present invention.

FIG. 5 is a third process schematic view showing a flexible OLED device of the first embodiment according to the present invention.

FIG. 6 is a fourth process schematic view showing a flexible OLED device of the first embodiment according to the present invention.

FIG. 7 is a fifth process schematic view showing a flexible OLED device of the first embodiment according to the present invention.

FIG. 8 is a sixth process schematic view showing a flexible OLED device of the first embodiment according to the present invention.

FIG. 9 is a seventh process schematic view showing a flexible OLED device of the first embodiment according to the present invention.

FIG. 10 is a second process schematic view showing a flexible OLED device of the second embodiment according to the present invention.

FIG. 11 is a third process schematic view showing a flexible OLED device of the second embodiment according to the present invention.

FIG. 12 is a fourth process schematic view showing a flexible OLED device of the second embodiment according to the present invention.

FIG. 13 is a fifth process schematic view showing a flexible OLED device of the second embodiment according to the present invention.

FIG. 14 is a sixth process schematic view showing a flexible OLED device of the second embodiment according to the present invention.

FIG. 15 is a seventh process schematic view showing a flexible OLED device of the second embodiment according to the present invention.

### PARTS LIST

| | | | |
|---|---|---|---|
| 1. | Flexible substrate | 2. | Insulating layer |
| 3. | Thin film transistor layer | 4. | Planarization film |
| 5. | Pixel defining layer | 51. | Protrusion |
| 6. | Organic light emitting layer | 7. | Thin film encapsulation layer |
| 81. | Bottom side of a notch | 82. | Left side surface of a notch |
| 83. | Right side surface of a notch | 9. | First material |

### DETAILED DESCRIPTION OF PREFERRED EMBODIMENTS

The preferred embodiments of the present invention are described in detail below with reference to the accompanying drawings to prove that the invention can be implemented. The technical content of the present invention will be made clearer so that those skilled in the art can more easily understand how to implement the present invention. However, the invention can be embodied in many different forms of embodiment. The scope of the present invention is not limited to the embodiments mentioned herein, and the description of the embodiments below is not intended to limit the scope of the invention.

The directional terms mentioned in the present invention, such as “upper”, “lower”, “front”, “rear”, “left”, “right”, “inside”, “outside”, used in the drawings are intended to be illustrative of the invention instead of limiting the scope of the invention.

In the drawings, structurally identical components are denoted by the same reference numerals, and structural or functionally similar components are denoted by like reference numerals. Moreover, the size and thickness of each component shown in the drawings are arbitrarily shown for ease of understanding and description, and the invention does not limit the size and thickness of each component.

When a component is described as “on” another component, the component can be disposed directly on another component, there can also be an intermediate component disposed on another component, and the component is disposed on the intermediate component. When a component is described as “mounted to” or “connected to” another component, it can be understood as either the component is “directly mounted to” or “directly connected to” another component, or the component is “mounted to” or “connected to” another component through an intermediate component.

### First Embodiment

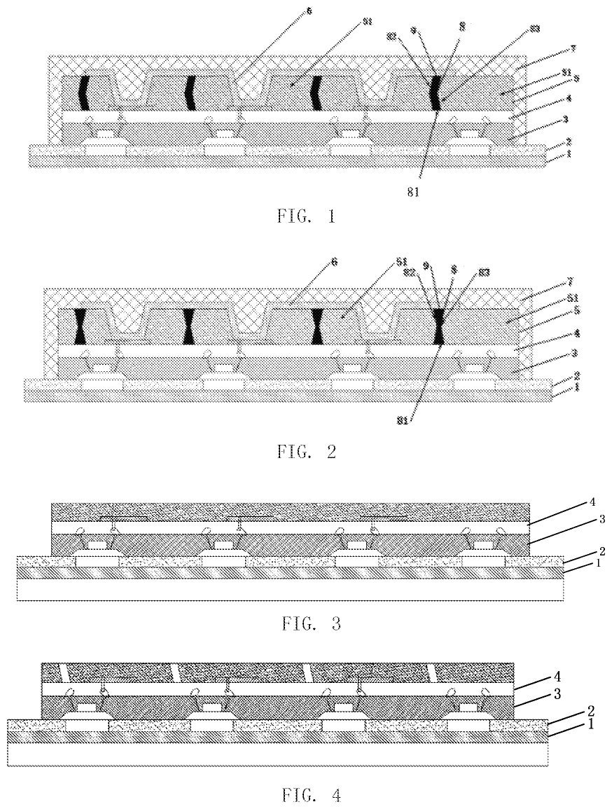

As shown in FIG. 1, a flexible OLED device of the present embodiment includes a flexible substrate 1, an insulating layer 2, a thin film transistor layer 3, a planarization layer 4, a pixel defining layer 5, an organic light emitting layer 6, and a thin film encapsulation layer 7, which are sequentially disposed on.

A fabrication method of the flexible substrate is coating PI (Polyimide Film) film on a clean glass substrate by a PI coater, and then processed by a high-temperature curing. Because PI has an excellent high and low temperature resistance, electrical insulation, adhesion, radiation resistance, and dielectric resistance, a PI substrate made of PI has good flexibility.

The insulating layer 2 disposed on the flexible substrate 1 is generally made of Silicon Nitride (SiNx) and Silicon Oxide (SiOx), thereby making the insulating layer 2 has a uniform density and a flat plane.

The thin film transistor layer 3 is disposed on the insulating layer 2. The planarization layer 4 is disposed on the thin film transistor layer 3. A gate electrode, a source electrode, and a drain electrode are provided in the thin film transistor 3 and the planarization layer 4. When a positive voltage is applied to the gate electrode, an electric field is generated between the gate electrode and a semiconductor layer. Under this electric field, an electron flow path is formed to form electrical conduction between the source electrode and the drain electrode. The larger the voltage applied to the gate electrode, the more electrons are attracted, so the current is larger. When a negative voltage is applied to the gate electrode, there is no current flow between the gate electrode and the drain electrode.

The organic light emitting layer 6 is disposed on the pixel defining layer 5, wherein the organic light emitting layer 6 includes a HTL, an EL, and an ETL. The HTL is disposed on the PI substrate, the EL is disposed on the HTL and the ETL is disposed on the EL. The HTL controls transport of holes, thereby controlling recombination of holes with electrons in the EL, thereby improving luminous efficiency. The ETL controls transport of electrons, thereby controlling recombination of electrons with holes in the EL, thereby improving luminous efficiency.

The thin film encapsulation layer 7 is covering the pixel defining 5 and the organic light emitting layer 6 to effectively prevent internal structures of the flexible OLED device from being eroded by water and oxygen, thereby effectively improving a lifetime of the flexible OLED device.

The pixel defining layer 5 is disposed on the planarization layer 4, wherein the pixel defining layer 5 is provided with a plurality of openings and a plurality of protrusions 51, wherein the protrusions 51 are disposed between each of two adjacent openings.

At least one of the planarization layer 4, the protrusions 51 of the pixel defining layer 5 and the thin film encapsulation layer 7 is provided with a notch passing through at least one film layer in which the planarization layer 4, the protrusion 51 of pixel defining layer 5 or the thin film encapsulation layer 7 is located. The plurality of notches are formed in a film layer in which each of the notches is defined, wherein the notches are regularly spaced. Each of the notches includes a bottom surface 81, a left side surface 82 and a right side surface 83. At least one of the left side surface 82 and the right side surface 83 is in the shape of a curved surface, a wavy surface, a single bending surface, a continuous bending surface, a concave surface, a convex surface or a combination of the above shapes.

In the present embodiment, each of the protrusions 51 of the pixel defining layer 5 is provided with at least one notch passing through the pixel defining layer 5 from an upper surface of the pixel defining layer 5 to an upper surface of the planarization layer 4. Both of the left side 82 and the right side 83 of the notch are in the shape of a single bending surface and have the same bending direction. A bending angle between the left side 82 and the right side 83 of the notch ranges from 60 degrees to 180 degrees. It is hard to make the bending angle of the left side surface 82 and the right side surface 83 of the notch less than 60 degrees by means of current process technology. An effect of enhancing the flexibility performance is not significant if the bending angle of the left side surface 82 and the right side surface 83 of the notch is larger than 180 degrees.

The notch is filled with a first material 9, wherein an elastic modulus of the first material is less than 100 Mpa. Specifically, the first material 9 can be PVC or POE. By utilizing the first material 9, flexibility of a flexible OLED device is improved, and the flexible OLED device that can be bent inward and outward is realized.

The notch is formed by photolithography, wherein photolithography includes wet etching and dry etching. Wet etching is a technique that an etching material is immersed in a bath of etchant for corrosion. Wet etching is a chemical etching method with excellent selectivity. The etchant will not attack another layer below after a desired film is etched. Dry etching is a technique using plasma for corrosion. When a gas exists in the form of plasma, it has two characteristics: 1. Chemical activity of gas in the form of plasma is much stronger than chemical activity of the gas in the normal state. According to different materials to be etched, an appropriate gas can be selected to react with the materials more quickly and achieve the purpose of etching removal. 2. An electric field can be used to guide and accelerate the plasma to have sufficient energy. When the plasma with sufficient energy bombards the surface of a material to be etched, atoms of the material to be etched will be knocked, thereby achieving the purpose of realizing etching removal by utilizing physical energy transfer.

### Second Embodiment

Only the differences between the present embodiment and the embodiment 1 will be described below, and the same portions will not be described herein.

As shown in FIG. 2, In the present embodiment, each of the protrusions 51 of the pixel defining layer 5 is provided with at least one notch passing through the pixel defining layer 5 from an upper surface of the pixel defining layer 5 to an upper surface of the planarization layer 4. Both of the left side 82 and the right side 83 of the notch are in the shape of a single bending surface. The left side 82 and the right side 83 of the notch have opposite bending directions. A bending angle between the left side 82 and the right side 83 of the notch ranges from 60 degrees to 180 degrees. It is hard to make the bending angle between the left side surface 82 and the right side surface 83 of the notch less than 60 degrees by means of current process technology. An effect of enhancing the flexibility performance is not significant if the bending angle between the left side surface 82 and the right side surface 83 of the notch is larger than 180 degrees.

The notch is filled with a first material 9, wherein an elastic modulus of the first material is less than 100 Mpa. Specifically, the first material 9 can be PVC or POE. By utilizing the first material 9, flexibility of a flexible OLED device is improved, and the flexible OLED device that can be bent inward and outward is realized.

### Third Embodiment

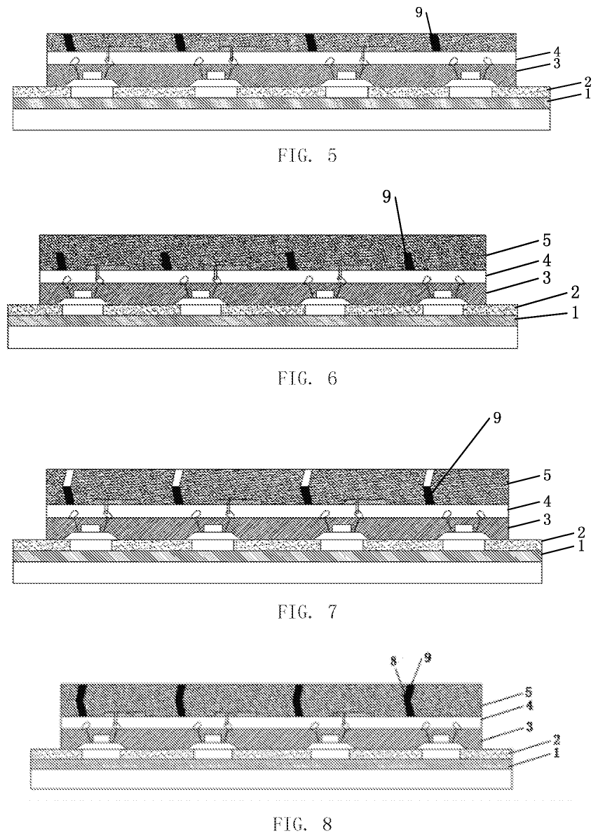

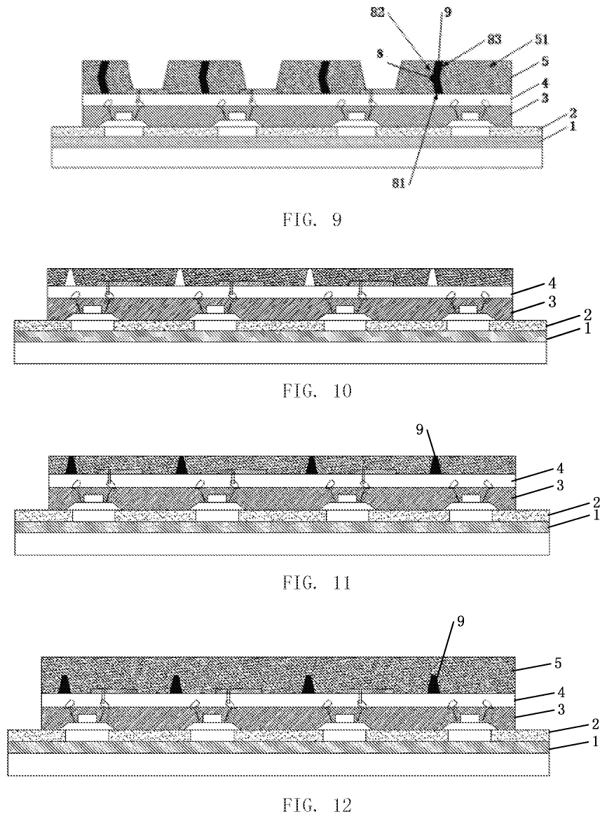

Referring to FIGS. 3-9, the present embodiment provides a fabrication method of an OLED device of the embodiment 1 according to the present invention. The fabrication method is described as follows: Providing a glass substrate, coating PI liquid on the glass substrate by a PI coater, and then manufacturing a flexible substrate 1 by a high-temperature curing. An insulating layer 2, a thin film transistor layer 3, and a planarization layer 4 are disposed on the flexible substrate 1 sequentially. A first pixel defining layer is disposed on the planarization layer 4. A plurality of first notches passing through the first pixel defining layer are formed by photolithography. Each of the first notches is filled with a first material 9. A second pixel defining layer is disposed on the first pixel defining layer. A plurality of second notches passing through the second pixel defining layer are formed by photolithography, wherein each of the second notches is symmetrical with each of the first notches respectively with respect to an upper surface of the first pixel defining layer. Each of the second notches is filled with the first material, thereby forming a pixel defining 5 with at least one notch 8. Exposing and developing the pixel defining layer 5. An organic light emitting layer 6 and the thin film encapsulation layer 7 are sequentially disposed on the pixel defining 5. Finally, a flexible OLED device as shown in FIG. 1 is formed.

### Fourth Embodiment

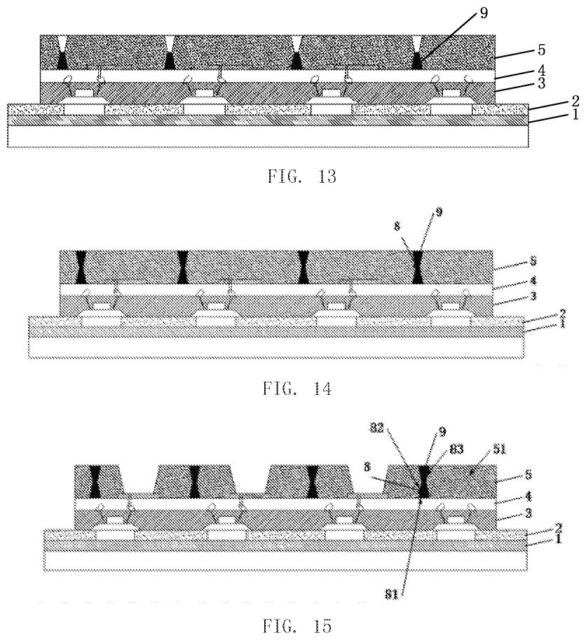

As shown in FIG. 3 and FIG. 10 to FIG. 15, the present embodiment provides a fabrication method of an OLED device of the embodiment 2 according to the present invention. The fabrication method is described as follows: Providing a glass substrate, coating PI liquid on the glass substrate by a PI coater, and then manufacturing a flexible substrate 1 by a high-temperature curing. An insulating layer 2, a thin film transistor layer 3, and a planarization layer 4 are disposed on the flexible substrate 1 sequentially. A first pixel defining layer is disposed on the planarization layer 4. A plurality of first notches passing through the first pixel defining layer are formed by photolithography. Each of the first notches is filled with a first material 9. A second pixel defining layer is disposed on the first pixel defining layer. A plurality of second notches passing through the second pixel defining layer are formed by photolithography, wherein each of the second notches is symmetrical with each of the first notches respectively with respect to an upper surface of the first pixel defining layer. Each of the second notches is filled with the first material, thereby forming a pixel defining 5 with at least one notch 8. Exposing and developing the pixel defining layer 5. An organic light emitting layer 6 and the thin film encapsulation layer 7 are sequentially disposed on the pixel defining 5. Finally, a flexible OLED device as shown in FIG. 2 is formed.

What is claimed is:

1. A flexible organic light emitting diode (OLED) device, comprising:
a flexible substrate;
an insulating layer disposed on the flexible substrate;
a thin film transistor layer disposed on the insulating layer;
a planarization layer disposed on the thin film transistor layer;
a pixel defining layer disposed on the planarization layer, wherein a plurality of openings and a plurality of protrusions are disposed on the pixel defining layer alternatively;
an organic emitting layer disposed on the pixel defining layer; and
a thin film encapsulation layer covering the pixel defining layer and the organic emitting layer;
wherein at least one of the planarization layer, the protrusion of pixel defining layer and the thin film encapsulation layer is provided with a notch passing through at least one film layer in which the planarization layer, the protrusion of the pixel defining layer or the thin film encapsulation layer is located, and the notch is filled with a first material.

2. The flexible OLED device as claimed in claim 1, wherein the plurality of notches are alternatively disposed to each other in a film layer in which the notches are located.

3. The flexible OLED device as claimed in claim 1, wherein the notch comprises:
a bottom surface;
a left side surface and a right side surface connected to a film layer in which the notch is defined, wherein at least one of the left side surface and the right side surface is in the shape of a curved surface, a wavy surface, a single bending surface, a continuous bending surface, a concave surface, a convex surface or a combination of the above shapes.

4. The flexible OLED device as claimed in claim 3, wherein the left side surface and the right side surface are in the shape of a single bending surface, and bending directions of the left side surface and the right side surface of each of the notches are the same.

5. The flexible OLED device as claimed in claim 3, wherein the left side surface and the right side surface are in the shape of a single bending surface, and bending directions of the left side surface and the right side surface are opposite.

6. The flexible OLED device as claimed in claim 4, wherein a bending angle between the left side surface and the right side surface ranges from 60 degrees to 180 degrees.

7. The flexible OLED device as claimed in claim 5, wherein a bending angle between the left side surface and the right side surface ranges from 60 degrees to 180 degrees.

8. The flexible OLED device as claimed in claim 1, wherein an elastic modulus of the first material is less than 100 Mpa.

9. The flexible OLED device as claimed in claim 1, wherein the first material is Polyvinylchloride (PVC) or Polyolefin Elastomer (POE).

10. A fabrication method of a flexible organic light emitting diode (OLED) device, comprising:
S1: providing a glass substrate, coating Polyimide (PI) liquid on the glass substrate by a PI coater, and then manufacturing a flexible substrate by a high temperature curing, and an insulating layer, a thin film transistor layer, a planarization layer and a pixel defining layer are sequentially formed on the flexible substrate, wherein a plurality of openings and a plurality of protrusions are disposed on the pixel defining layer alternatively;
S2: forming a notch through the film layer of at least one of the planarization layer, the protrusion of the pixel defining layer and a thin film encapsulating layer by photolithography, and then filling the first material in the notch;
S3: exposing and developing the pixel defining layer;
S4: forming an organic emitting layer and the thin film encapsulation layer on the pixel defining layer.
